(19) United States
(12) Patent Application Publication
(10) Pub. No.: US 2010/0252309 A1
(43) Pub. Date: Oct. 7, 2010

(54) POLYIMIDE FILM AND WIRING BOARD

(75) Inventors: Hiroaki Yamaguchi, Yamaguchi (JP); Tadahiro Yokozawa, Chiba (JP); Shuichi Maeda, Yamaguchi (JP)

Correspondence Address: KNOBBE MARTENS OLSON & BEAR LLP, 2040 MAIN STREET, FOURTEENTH FLOOR, IRVINE, CA, 92614, US

(73) Assignee: UBE INDUSTRIES, LTD., Ube-shi, Yamaguchi (JP)

(21) Appl. No.: 12/671,011

(22) PCT Filed: Jul. 25, 2008
(86) PCT No.: PCT/JP2008/063450

§ 371 Date: Mar. 3, 2010

(30) Foreign Application Priority Data
Jul. 27, 2007 (JP) 2007-196695

(51) Int. Cl. H05K 1/09; B32B 15/088; C08G 73/10; B32B 27/34; H05K 3/02; H05K 1/00

(52) U.S. Cl. 174/257; 428/473.5; 428/447; 427/385.5; 216/13; 174/258

(57) ABSTRACT

The polyimide film of the present invention is to be used for the production of a wiring board having a metal wiring, which is formed by forming a metal layer on one side (Side B) of the polyimide film, and etching the metal layer; the polyimide film is curled toward the side (Side A) opposite Side B; and the curling of the polyimide film is controlled so as to reduce the drooping of the wiring board having a metal wiring formed thereon. The handling characteristics and productivity in IC chip mounting may be improved by the use of the polyimide film.

### TECHNICAL FIELD

The present invention relates to a polyimide film having controlled curling, which is particularly suitable as a film for COF. The present invention also relates to a wiring board comprising the polyimide film.

### BACKGROUND ART

A polyimide film has been widely used in electronic device applications, for example, because it has excellent thermal and electric properties. Recently, an IC chip has been mounted by a COF (chip on film) method, and a copper-laminated polyimide film in which a copper layer is laminated on a polyimide film has been used for COF (Patent document 1, etc.).

Conventionally, such a copper-laminated polyimide film may be produced as follows:

Firstly, a self-supporting film of a polyimide precursor solution is prepared by flow-casting a polyimide precursor solution on a support such as a stainless substrate and a stainless belt, and drying and heating it sufficiently to make it self-supporting, which means a stage before a common curing process. Subsequently, for the purpose of improving adhesive properties, sputtering properties (suitability for sputtering) and metal vapor deposition properties (suitability for metal vapor deposition) of the polyimide film obtained, a solution of a coupling agent is applied to the surface of the self-supporting film of the polyimide precursor solution. A coupling agent solution is generally applied onto a side (Side B) of the self-supporting film which has been in contact with the support when producing the film. And then, the self-supporting film is heated to effect imidization, thereby producing a polyimide film. A copper-laminated polyimide film may be produced by forming a copper layer by a known method such as a metallizing method on the surface of the polyimide film obtained to which the coupling agent solution is applied.

When using the copper-laminated polyimide film as described above for COF, however, a problem associated with handling characteristics and productivity may arise in IC chip mounting. The problem will be described with reference to a drawing. A predetermined copper wiring is formed by etching the copper layer of the copper-laminated polyimide film. And then, an IC chip is mounted on the copper wiring. As shown in FIG. 1, a copper-laminated polyimide film is generally conveyed with one edge fixed and the copper layer side down, and an IC chip is mounted on the underside of the film carrier tape. When an IC chip is mounted thereon, the film carrier tape may droop due to the weight of the IC chip, and therefore may not pass through the production line. Such a problem may arise frequently when using a polyimide film prepared from 3,3′,4,4′-biphenyltetracarboxylic dianhydride and p-phenylenediamine by thermal imidization.

Meanwhile, when a polyimide film is treated with a coupling agent, adhesiveness of the treated surface is improved but the film may be curled. However, it is difficult to control the curling of the polyimide film precisely. It is difficult to control a curling surface (a concave surface after curling of the polyimide film). It is more difficult to control a direction and an amount of curling.

Patent document 2 discloses that the curling level may be reduced by a combination of multiple steps in which the conditions are optimized; specifically controlling a volatile content and an imidization rate of a solidified thin film (cast film) on a support to within a given range when producing the film; controlling a volatile content and an imidization rate of the solidified film to within a given range after drying the film without fixing both widthwise edges; heating the dried film at a high temperature with both widthwise edges fixed, to effect imidization; and finally subjecting the film to stress relief treatment. Patent document 2 also discloses that the optimum drying conditions depends on the thickness of the film, as well as conditions such as the drying temperature and temperature gradient, and the drying time; and therefore the optimum conditions may be found by determining the curling level of the polyimide film which is prepared under certain conditions, and then varying the curling level based on the curling surface (A or B) and the degree of curling, preferably by modifying the production conditions such as temperature.

Patent document 3 discloses a method wherein the curling of the polyimide film is controlled by adjusting an application amount of an organic liquid which is applied to one side of the self-supporting film, a solution of a coupling agent in an organic solvent being applied to the other side.

Patent document 4 discloses that the curling of the polyimide film increases as the orientation ratio between the front and back surfaces of the film (the orientation ratio between the surface and the opposite surface of the film, i.e. the difference in the orientation of polymer chains between the front and back surfaces of the film which is generated in a stretching step in the production of the film) increases, particularly in a biaxially oriented polyimide film prepared from the combination of pyromellitic dianhydride and 4,4′-diaminodiphenyl ether by the chemical cyclization. Patent document 4 also discloses that twist generates according to the difference in the orientation as the difference in the angle of the orientation main axis between the front and back surfaces of the film (the direction in which the orientation parameter is greatest for each surface) increases. In addition, Patent document 4 discloses that it is essential to peel the film from the support so that the film has a draw ratio of 1.01 to 1.2 immediately after peeling, and to control the surface temperature of the support to be an ambient temperature +35° C. or lower and within a range of 50° C. to 100° C.

Patent document 5 discloses that in a biaxially oriented polyimide film prepared by the chemical cyclization, particularly in a biaxially oriented polyimide film prepared from the combination of pyromellitic dianhydride and 4,4′-diaminodiphenyl ether, or the combination of 3,3′,4,4′-biphenyltetracarboxylic dianhydride and p-phenylenediamine by the chemical cyclization, the average in-plane thermal expansion coefficient is reduced when fully oriented, and the curling of the flexible copper-laminated polyimide film is reduced when the in-plane anisotropy index is reduced by controlling the draw ratio between the running direction and the width direction.

In addition, Patent document 6 discloses that the curling after heat treatment (hot air treatment at 400° C. for 10 min) of the polyimide film obtained is reduced when the difference in the degree of the orientation between the front and back surfaces of the polyimide film is reduced by controlling the production conditions for preparing a polyamide acid film from a polyamide acid solution; specifically controlling the drying conditions for drying the polyamide acid solution to self-supporting such as the difference in the temperature between the upper and lower surfaces of the support, and the content of the residual solvent after drying, followed by imidization of the polyamide acid film.

Patent document 1: JP-A-2006-124685;

Patent document 2: JP-A-H10-77353;

Patent document 3: WO2006/109753;

Patent document 4: JP-A-2000-85007;

Patent document 5: JP-A-H05-237928;

Patent document 6: JP-A-2005-194318.

### DISCLOSURE OF THE INVENTION

### Problems to be Solved by the Invention

As described above, when a copper-laminated polyimide film is used for COF and an IC chip is mounted directly on the copper-laminated polyimide film, the film carrier tape may droop due to the weight of the IC chip and may not pass through the production line.

An objective of the present invention is to prevent such a problem and to provide a polyimide film having controlled curling, which allows improvements in handling characteristics and productivity in IC chip mounting; and a wiring board produced by forming a metal wiring on Side B of the polyimide film.

### Means for Solving the Problems

The present invention relates to the followings.

[1] A polyimide film produced by

providing a solution of a polyimide precursor prepared from an aromatic tetracarboxylic acid component comprising 3,3′,4,4′-biphenyltetracarboxylic dianhydride as a main component and an aromatic diamine component comprising p-phenylenediamine as a main component;

flow-casting the polyimide precursor solution on a support, followed by heating, thereby preparing a self-supporting film of a polyimide precursor solution;

applying a solution containing a coupling agent onto one side (Side B) of the self-supporting film which has been in contact with the support when producing the film; and

heating the self-supporting film onto which the coupling agent solution is applied to effect imidization; wherein

the polyimide film is to be used for the production of a wiring board having a metal wiring, which is formed by forming a metal layer on one side (Side B) of the polyimide film, and etching the metal layer;

the polyimide film is curled toward the side (Side A) opposite Side B; and

the curling of the polyimide film is controlled so as to reduce the drooping of the wiring board having a metal wiring formed thereon.

[2] The polyimide film as described in [1], wherein the curling of the polyimide film is controlled so that the absolute value of the drooping amount of the wiring board having a metal wiring formed thereon (70 mm×50 mm, the remaining ratio of the metal layer: 50%) is 3.0 mm or less.

[3] The polyimide film as described in any of [1] to [2], wherein the metal wiring is a copper wiring.

[4] The polyimide film as described in any of [1] to [3], wherein the coupling agent is a silane coupling agent.

[5] The polyimide film as described in any of [1] to [4], wherein the curling of the polyimide film is controlled by adjusting at least one of the content of the solvent in the self-supporting film, the inlet temperature of the heating furnace for heating the self-supporting film to effect imidization, and the width of the film when both widthwise edges of the film are fixed in the heating furnace.

[6] A wiring board produced by

providing a solution of a polyimide precursor prepared from an aromatic tetracarboxylic acid component comprising 3,3′,4,4′-biphenyltetracarboxylic dianhydride as a main component and an aromatic diamine component comprising p-phenylenediamine as a main component;

flow-casting the polyimide precursor solution on a support, followed by heating, thereby preparing a self-supporting film of a polyimide precursor solution;

applying a solution containing a coupling agent onto one side (Side B) of the self-supporting film which has been in contact with the support when producing the film;

heating the self-supporting film onto which the coupling agent solution is applied to effect imidization, thereby preparing a polyimide film;

forming a metal layer on one side (Side B) of the polyimide film; and

etching the metal layer to form a metal wiring; wherein

the polyimide film is curled toward the side (Side A) opposite Side B; and

the curling of the polyimide film is controlled so as to reduce the drooping of the wiring board having a metal wiring formed on Side B of the polyimide film.

[7] The wiring board as described in [6], wherein the absolute value of the drooping amount of the wiring board having a metal wiring formed thereon (70 mm×50 mm, the remaining ratio of the metal layer: 50%) is 3.0 mm or less.

[8] The wiring board as described in any of [6] to [7], wherein the metal wiring is a copper wiring.

[9] The wiring board as described in any of [6] to [8], wherein the coupling agent is a silane coupling agent.

[10] The wiring board as described in any of [6] to [9], wherein the curling of the polyimide film is controlled by adjusting at least one of the content of the solvent in the self-supporting film, the inlet temperature of the heating furnace for heating the self-supporting film to effect imidization, and the width of the film when both widthwise edges of the film are fixed in the heating furnace.

[11] The wiring board as described in any of [6] to [10], wherein the metal layer consists of a metal sputtered underlayer consisting of a Ni/Cr layer having a thickness of 1 nm to 30 nm and a copper sputtered layer having a thickness of 100 nm to 1000 nm, and a copper plated layer having a thickness of 1 μm to 9 μm.

The term “drooping amount (70 mm×50 mm, the remaining ratio of the metal layer: 50%)” as used herein refers to a deviation of a long side which is free (not fixed) from a horizontal plane (a long side which is fixed) when a wiring board, which is prepared from a rectangular metal-laminated polyimide film (70 mm×50 mm) by forming a metal wiring with a remaining metal ratio of 50% by etching, is fixed over 2 mm of a long side along the direction of the short side with the metal wiring side down, as shown in FIG. 3(b). The plus sign indicates that the direction is downward.

The term “drooping amount (70 mm×50 mm, the remaining ratio of the metal layer: 80%)” as used herein refers to a deviation of a long side which is free (not fixed) from a horizontal plane (a long side which is fixed) when a wiring board, which is prepared from a rectangular metal-laminated polyimide film (70 mm×50 mm) by forming a metal wiring with a remaining metal ratio of 80% by etching, is fixed over 2 mm of a long side along the direction of the short side with the metal wiring side down, as shown in FIG. 3(b). The plus sign indicates that the direction is downward.

The wiring board for determination of drooping amount has a straight metal wiring along the direction of the short side, for example, as shown in FIG. 3(a). A film is generally conveyed in this direction. The wiring pitch is preferably about 0.1 mm to about 1 mm.

### EFFECT OF THE INVENTION

According to the present invention, a polyimide film the curling of which is controlled so as to reduce the drooping of the wiring board having a metal wiring formed on one side (Side B) thereof is used for COF. The drooping of the wiring board having a metal wiring formed thereon may include the drooping of the wiring board with or without an IC chip mounted thereon. The control of the curling of the polyimide film allows the film carrier tape to pass through the production line reliably, resulting in improvements in handling characteristics and productivity in IC chip mounting. Accordingly, it is required to control a curling surface and a curling amount of the polyimide film. In case the film carrier tape droops and cannot pass through the production line when an IC chip is mounted thereon, the curling of the polyimide film can be controlled to prevent such a problem.

### BRIEF DESCRIPTION OF THE DRAWINGS

FIG. 1 illustrates fabrication trouble that occurs when an IC chip is mounted on a copper-laminated polyimide film.

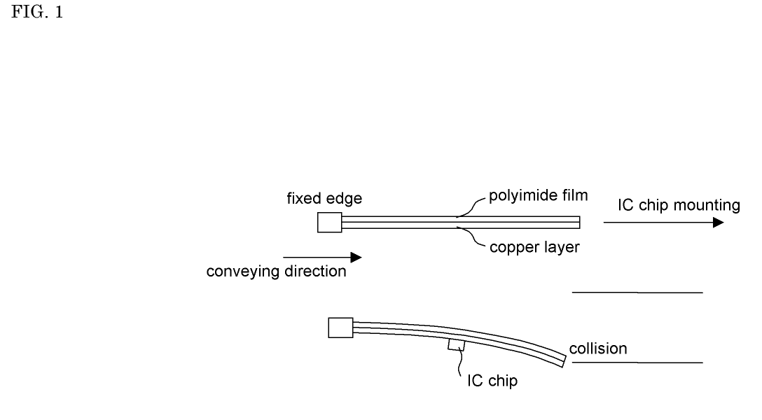

FIG. 2 illustrates an example of the process for forming a metal wiring (copper wiring) on the polyimide film of the present invention; and then mounting an IC chip on the metal wiring.

FIG. 3 illustrates drooping and drooping amount of a wiring board.

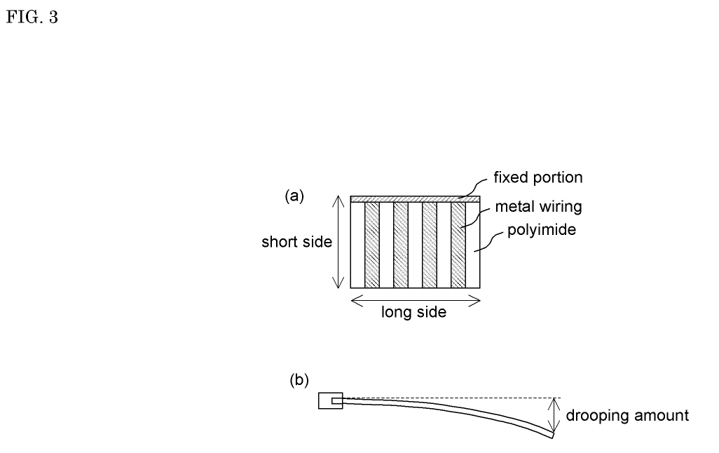

FIG. 4 illustrates a method of determining curling amount of a polyimide film.

### BEST MODE FOR CARRYING OUT THE INVENTION

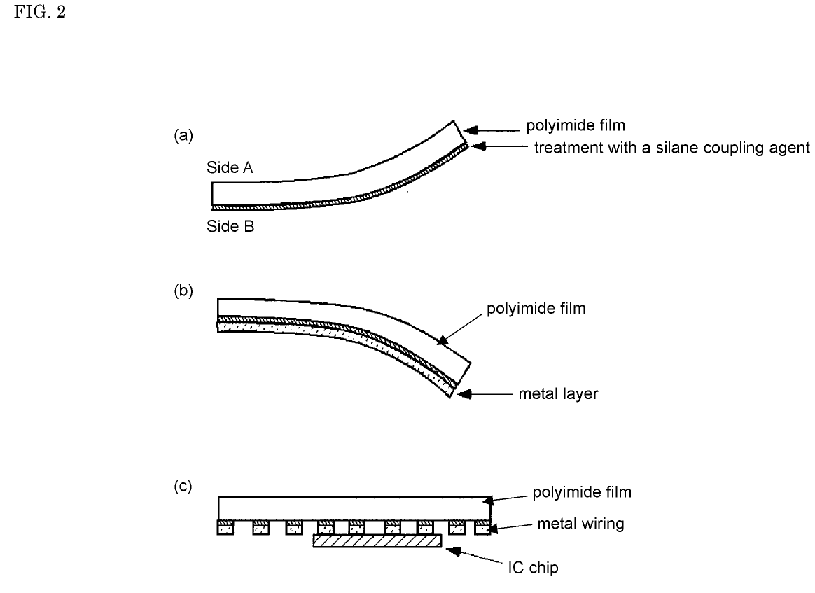

FIG. 2 illustrates an example of the process for forming a metal wiring (copper wiring) on the polyimide film of the present invention; and then mounting an IC chip on the metal wiring.

In general, a metal wiring (copper wiring) is formed and an IC chip is mounted on one side (Side B) of a polyimide film which was in contact with the support when producing the self-supporting film thereof. The polyimide film used in the present invention is curled toward the side (Side A) opposite Side B which is treated with a coupling agent, as shown in FIG. 2(a). Moreover, the curling of the polyimide film is controlled so as to reduce the drooping of the wiring board having a metal wiring formed thereon so that the film may pass through a production line in the process for forming a metal wiring and mounting an IC chip thereon without fail.

As shown in FIG. 2(b), a metal layer is formed on Side B of the polyimide film by a known method such as a metallizing method. When forming a metal layer thereon, the film usually droop toward Side B due to the weight of the metal layer. In the present invention, the use of a polyimide film which is curled toward Side A allows the reduction in the drooping amount.

And then, the metal-laminated polyimide film is conveyed with one edge fixed and the metal layer side down, and the metal layer is etched to form a metal wiring, as shown in FIG. 2(c). The metal wiring is preferably a copper wiring. According to the present invention, the curling of the polyimide film is controlled so as to reduce the drooping of the wiring board at that time, and therefore the absolute value of the drooping amount of the wiring board obtained is small. Specifically, the absolute value of the drooping amount of the wiring board (70 mm×50 mm, the remaining ratio of the metal layer: 50%) is preferably 3.0 mm or less, more preferably 2.5 mm or less, further preferably 2.0 mm or less, particularly preferably 1.5 mm or less. In addition, the absolute value of the drooping amount of the wiring board (70 mm×50 mm, the remaining ratio of the metal layer: 80%) is preferably 6.0 mm or less, more preferably 5.0 mm or less, further preferably 4.0 mm or less, particularly preferably 3.5 mm or less.

Subsequently, an IC chip is mounted on the metal wiring of the wiring board. According to the present invention, the curling of the polyimide film is also controlled so as to reduce the drooping of the wiring board at that time. The absolute value of the drooping amount of the wiring board (70 mm×50 mm, the remaining ratio of the metal layer: 50%) with an IC chip mounted thereon is also small. Specifically, it is preferably 2.0 mm or less, more preferably 1.5 mm or less, further preferably 1.0 mm or less, particularly preferably 0.5 mm or less. The absolute value of the drooping amount of the wiring board tends to be smaller as the short side of the wiring board is shorter.

The drooping amount of the wiring board before mounting an IC chip thereon may be preferably determined and controlled with consideration for the fact that the wiring board may droop more due to the weight of the IC chip when mounting an IC chip thereon. If necessary, the drooping amount may be negative, that is, the wiring board before mounting an IC chip thereon may be curled upward.

As described above, according to the present invention, the curling of the polyimide film is controlled so as to reduce the drooping of the wiring board having a metal wiring formed thereon. The drooping may vary with the metal wiring pattern formed. Accordingly, it is required to control the curling of the polyimide film depending on the desired metal wiring pattern.

In the present invention, a polyimide film having the desired curling may be obtained by appropriately adjusting the conditions (heating temperature, heating time) for heating the polyamic acid solution used for the preparation of the self-supporting film, and the self-supporting film; the content of the solvent in the self-supporting film; the imidization rate of the self-supporting film; the amount of the coupling agent solution to be applied to the self-supporting film; the conditions (heating temperature, width-direction stretch ratio of the film) for imidizing/heating the self-supporting film; and the like, for example, to control the curling of the polyimide film.

As an example of the preparation of the polyimide film having the desired curling, the content of the solvent in the self-supporting film may be adjusted to control the curling. The curling surface is more apt to be Side A than Side B when the content of the solvent in the self-supporting film is high. Meanwhile, when the content of the solvent in the self-supporting film is excessively high, cracks and the like may be observed in the polyimide film obtained after imidization. Although the preferable content of the solvent in the self-supporting film is dependent on the apparatus to be used, and the other production conditions, it may be preferably about 35 wt % to about 45 wt %, more preferably about 38 wt % to about 44 wt %.

Herein, the content of the solvent in the self-supporting film is calculated by the following numerical equation from the weight before drying (W1) and the weight after drying (W2) of the self-supporting film (10 cm×10 cm) which is dried at 400° C. for 30 min.

Content of Solvent in Self-supporting Film (wt %)={(W1−W2)/W1}×100

The content of the solvent in the self-supporting film may be controlled to within the desired range by adjusting a heating temperature for heating the polyimide precursor solution which is flow-cast on a support to prepare the self-supporting film of the polyimide precursor solution (casting temperature). The content of the solvent in the self-supporting film prepared tends to increase as the casting temperature decreases. Although the preferable casting temperature is dependent on the heating time, the apparatus to be used, and the other production conditions, it may be preferably 130° C. to 170° C., more preferably 140° C. to 155° C.

Furthermore, the imidization rate of the self-supporting film may be preferably controlled to within a range of 5% to 40%, more preferably 7% to 30%.

The imidization rate of the self-supporting film may be calculated based on the ratio of the vibration band peak area measured by IR spectrometer (ATR) between the self-supporting film and the fully-cured product (produced by heating the film at 400° C. for 30 min to effect imidization). The vibration band peak utilized in the procedure may be a symmetric stretching vibration band of an imide carbonyl group and a stretching vibration band of a benzene ring skeleton.

In the IR spectrum of the fully-imidized film, the ratio of the peak area corresponding to an imide group at 1747 cm⁻¹ to 1798 cm⁻¹ to the peak area corresponding to an benzene ring at 1432 cm⁻¹ to 1560 cm⁻¹ is calculated, the baseline being defined based on the peak corresponding to an imide group. Meanwhile, in the IR spectrum of the self-supporting film, the ratio is calculated in the same way. And then, the imidization rate of the self-supporting film to the fully-imidized film is calculated from these ratios.

In addition, the curling amount toward Side A of the polyimide film obtained may be controlled by adjusting the inlet temperature of the heating furnace for heating the self-supporting film to effect imidization (curing oven). Although the preferable inlet temperature of the curing oven is dependent on the apparatus to be used, and the other production conditions, it may be preferably 150° C. or higher. The outlet temperature of the curing oven may be the highest heating temperature for imidization, or lower. It may be preferably 220° C. or lower. The highest temperature in the curing oven may be preferably about 350° C. to about 600° C.

Furthermore, a polyimide film which is curled toward Side A may be obtained by drawing the film in the width direction during imidization; specifically by stretching the film in the width direction in the heating furnace for imidization (curing oven). Although the preferable width-direction stretch ratio of the film is dependent on the apparatus to be used, and the other production conditions, it may be preferably about 0% to about 30%, more preferably about 0% to about 15%.

In the present invention, it is particularly preferable that the content of the solvent in the self-supporting film is controlled to within the above-mentioned range, and the inlet temperature of the curing oven and/or the width of the film when both widthwise edges of the film are fixed in the curing oven is controlled. The polyimide film thus obtained may be curled larger toward Side A.

The curling amount toward Side A may be preferably controlled to within a range of −14 mm to −30 mm, more preferably −16 mm to −28 mm, further preferably −18 mm to −26 mm, particularly preferably −19 mm to −24 mm, for example.

The method of determining curling of a polyimide film will now be described below.

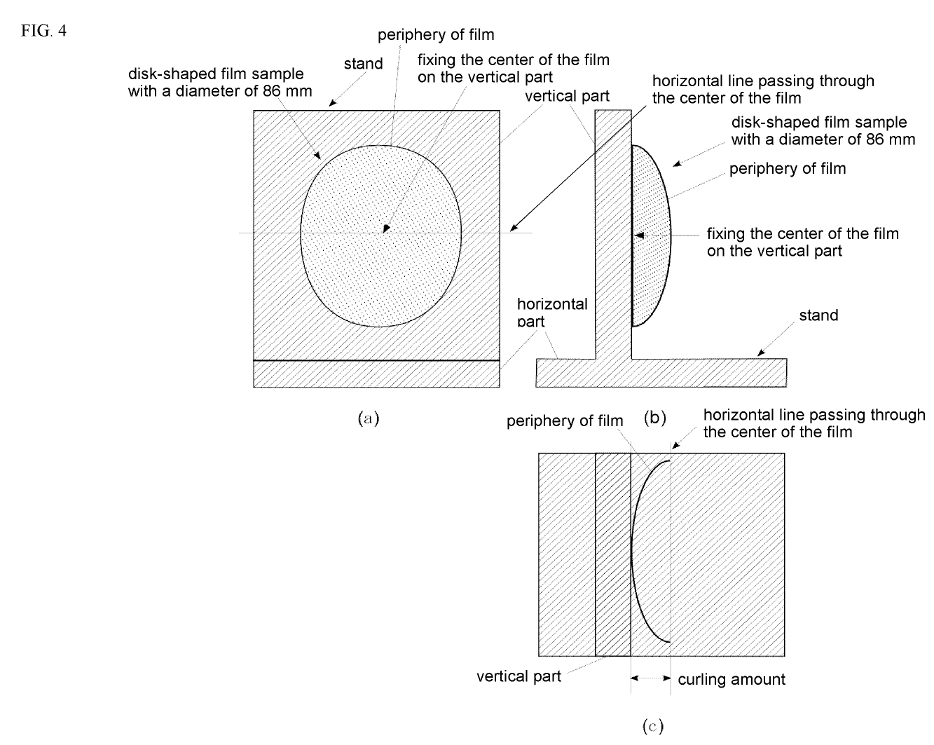

The determination of curling is carried out at 23° C. and 50% RH (relative humidity). As shown in FIG. 4(b), a stand for a film comprising a horizontal part and a vertical part is used to determine curling. As a sample for determination of the curling amount, a disk-shaped sample with a diameter of 86 mm is cut out, and is heated at 110° C. for 10 min and then left in an atmosphere at 23° C. and 50% RH for 1 hour for humidity-conditioning to remove a winding curl. After humidity-conditioning, the curling amount of the sample is determined.

FIGS. 4(a), 4(b) and 4(c) illustrate a method of fixing a sample on a stand and determining the curling amount of the sample. FIG. 4(a) is a front view; FIG. 4(b) is a side view; and FIG. 4(c) is a top view.

As shown in FIGS. 4(a) and 4(b), a disk-shaped sample is placed away from the horizontal part and convexly against the vertical part of the stand, and the center of the sample is fixed on the vertical part. For the purpose of determining the curling amount under the minimum influence of gravitation, the sample fixed on the vertical part is rotated so that the largest-curled point(s) of the periphery of the sample lie on the horizontal line passing through the center of the sample. And then, the distance between the largest-curled point(s) of the periphery and the vertical part of the stand is measured, and the measured value is taken as the curling amount (The minus sign indicates that the sample is curled toward Side A.).

As shown in FIGS. 4(b) and 4(c), the curling amount toward Side A is measured when a disk-shaped sample the curling of which is convex toward Side B (concave toward Side A) is fixed so that Side B of the sample is in contact with the vertical part of the stand.

As shown in FIG. 4(c), a disk-shaped sample is parabolically or semi-parabolically curled. A sample which is rolled up may be excluded.

When using a polyimide film for COF, a linear expansion coefficient of a polyimide film may be preferably close to that of copper. Specifically, the polyimide film may preferably have a linear expansion coefficient (both MD and TD) of 5×10⁻⁶ cm/cm/° C. to 25×10⁻⁶ cm/cm/° C., more preferably 10×10⁻⁶ cm/cm/° C. to 25×10⁻⁶ cm/cm/° C., particularly preferably 12×10⁻⁶ cm/cm/° C. to 20×10⁻⁶ cm/cm/° C.

According to the present invention, firstly, a self-supporting film of a polyimide precursor solution may be prepared by flow-casting a polyimide precursor solution on a support, and then heating it. Subsequently, a coupling agent solution is applied to Side B of the self-supporting film of the polyimide precursor solution (side which has been in contact with the support when producing the film). And then, the self-supporting film is heated to effect imidization, thereby producing a polyimide film.

A self-supporting film of a polyimide precursor solution may be prepared by flow-casting a solution of a polyimide precursor in an organic solvent to give a polyimide on a support, after adding an imidization catalyst, an organic phosphorous compound and/or an inorganic fine particle to the solution, if necessary, and then heating it sufficiently to make it self-supporting, which means a stage before a common curing process.

The polyimide precursor used in the present invention is prepared from an aromatic tetracarboxylic acid component comprising 3,3′,4,4′-biphenyltetracarboxylic dianhydride (hereinafter, sometimes abbreviated as “s-BPDA”) as a main component and an aromatic diamine component comprising p-phenylenediamine (hereinafter, sometimes abbreviated as “PPD”) as a main component. Specifically, an aromatic tetracarboxylic acid component may preferably comprise 50 mol % or more, more preferably 80 mol % or more, particularly preferably 90 mol % or more of s-BPDA. An aromatic diamine component may preferably comprise 50 mol % or more, more preferably 80 mol % or more, particularly preferably 90 mol % or more of PPD. In one embodiment, a preferable aromatic diamine component may be the combination of PPD and 4,4′-diaminodiphenyl ether (hereinafter, sometimes abbreviated as “DADE”). In this case, a ratio of PPD/DADE (molar ratio) is preferably 100/0 to 85/15. In one embodiment, a preferable aromatic tetracarboxylic acid component may be the combination of s-BPDA and pyromellitic dianhydride (hereinafter, sometimes abbreviated as “PMDA”). In this case, a ratio of s-BPDA/PMDA (molar ratio) is preferably 100/0 to 30/70.

A polyimide film prepared from an aromatic tetracarboxylic acid component comprising 3,3′,4,4′-biphenyltetracarboxylic dianhydride as a main component and an aromatic diamine component comprising p-phenylenediamine as a main component by thermal imidization is suitable as a film for COF. When using the polyimide film for COF, however, a problem associated with handling characteristics and productivity may arise in IC chip mounting for some apparatus, as described above. According to the present invention, the curling surface, curling direction and curling amount of such a polyimide film may be controlled, and therefore a polyimide film having the desired curling may be obtained. The use of the polyimide film of the present invention for COF allows improvements in handling characteristics and productivity in IC chip mounting.

A polyimide precursor may be synthesized by random-polymerizing or block-polymerizing substantially equimolar amounts of an aromatic tetracarboxylic dianhydride and an aromatic diamine in an organic solvent. Alternatively, two or more polyimide precursor solutions in which either of these two components is excessive may be prepared, and subsequently, these polyimide precursor solutions may be combined and then mixed under the reaction conditions. The polyimide precursor solution thus obtained may be used without any treatment, or may be used after removing or adding a solvent, if necessary, to prepare a self-supporting film.

Examples of an organic solvent for the polyimide precursor solution include N-methyl-2-pyrrolidone, N,N-dimethylformamide, N,N-dimethylacetamide and N,N-diethylacetamide. These organic solvents may be used alone or in combination of two or more.

The polyimide precursor solution may contain an imidization catalyst, an organic phosphorous-containing compound, an inorganic fine particle, and the like, if necessary.

Examples of the imidization catalyst include substituted or unsubstituted nitrogen-containing heterocyclic compounds, N-oxide compounds of the nitrogen-containing heterocyclic compounds, substituted or unsubstituted amino acid compounds, hydroxyl-containing aromatic hydrocarbon compounds, and aromatic heterocyclic compounds. Particularly suitable examples of the imidization catalyst include lower-alkylimidazoles such as 1,2-dimethylimidazole, N-methylimidazole, N-benzyl-2-methylimidazole, 2-methylimidazole, 2-ethyl-4-imidazole and 5-methylbenzimidazole; benzimidazoles such as N-benzyl-2-methylimidazole; and substituted pyridines such as isoquinoline, 3,5-dimethylpyridine, 3,4-dimethylpyridine, 2,5-dimethylpyridine, 2,4-dimethylpyridine and 4-n-propylpyridine. The amount of the imidization catalyst to be used is preferably about 0.01 to 2 equivalents, particularly preferably about 0.02 to 1 equivalents relative to the amount of an amide acid unit in a polyamide acid. When the imidization catalyst is used, the polyimide film obtained may have the improved properties, particularly extension and edge-cracking resistance.

Examples of the organic phosphorous-containing compound include phosphates such as monocaproyl phosphate, monooctyl phosphate, monolauryl phosphate, monomyristyl phosphate, monoacetyl phosphate, monostearyl phosphate, triethyleneglycol monotridecyl ether monophosphate, tetraethyleneglycol monolauryl ether monophosphate, diethyleneglycol monostearyl ether monophosphate, dicaproyl phosphate, dioctyl phosphate, dicapryl phosphate, dilauryl phosphate, dimyristyl phosphate, dicetyl phosphate, distearyl phosphate, tetraethyleneglycol mononeopentyl ether diphosphate, triethyleneglycol monotridecyl ether diphosphate, tetraethyleneglycol monolauryl ether diphosphate, and diethyleneglycol monostearyl ether diphosphate; and amine salts of these phosphates. Examples of the amine include ammonia, monomethylamine, monoethylamine, monopropylamine, monobutylamine, dimethylamine, diethylamine, dipropylamine, dibutylamine, trimethylamine, triethylamine, tripropylamine, tributylamine, monoethanolamine, diethanolamine and triethanolamine.

Examples of the inorganic fine particle include particulate inorganic oxide powders such as titanium dioxide powder, silicon dioxide (silica) powder, magnesium oxide powder, aluminum oxide (alumina) powder and zinc oxide powder; particulate inorganic nitride powders such as silicon nitride powder and titanium nitride powder; inorganic carbide powders such as silicon carbide powder; and particulate inorganic salt powders such as calcium carbonate powder, calcium sulfate powder and barium sulfate powder. These inorganic fine particles may be used alone or in combination of two or more. These inorganic fine particles can be homogeneously dispersed using a known method.

A self-supporting film of a polyimide precursor solution may be prepared by flow-casting the above-mentioned solution of a polyimide precursor in an organic solvent, or a polyimide precursor solution composition which is prepared by adding an imidization catalyst, an organic phosphorous-containing compound, an inorganic fine particle, and the like to the above solution, on a support; and then heating it to the extent that the film becomes self-supporting, which means a stage before a common curing process, for example, to the extent that the film may be peeled from the support.

A substrate having a smooth surface may be preferably used as a support for a self-supporting film of a polyimide precursor solution. The support to be used may be a stainless substrate or a stainless belt, for example.

As described above, according to the present invention, the heating temperature at that time (casting temperature) may be adjusted to control the content of the solvent in the self-supporting film prepared, thereby controlling the curling. The heating time may be appropriately determined, and it may be about 3 min to about 60 min, for example.

The self-supporting film thus obtained may preferably have a solvent content of 35 wt % to 45 wt %, more preferably 38 wt % to 44 wt %; and an imidization rate of 5% to 40%, more preferably 7% to 30%. However, these may not be limited to the above range, and may be appropriately selected so as to obtain a polyimide film having the desired curling.

According to the present invention, a solution containing a coupling agent is applied to Side B (side which has been in contact with the support when producing the film) of the self-supporting film thus obtained. If necessary, a coupling agent solution may be applied to both sides of the self-supporting film.

Examples of the coupling agent include a silane-based coupling agent, and a titanate-based coupling agent. Examples of the silane-based coupling agent include epoxysilane-based coupling agents such as γ-glycidoxypropyl trimethoxy silane, γ-glycidoxypropyl diethoxy silane, and β-(3,4-epoxycyclohexyl)ethyl trimethoxy silane; vinylsilane-based coupling agents such as vinyl trichloro silane, vinyl tris(β-methoxy ethoxy) silane, vinyl triethoxy silane, and vinyl trimethoxy silane; acrylsilane-based coupling agents such as γ-methacryloxypropyl trimethoxy silane; aminosilane-based coupling agents such as N-β-(aminoethyl)-γ-aminopropyl trimethoxy silane, N-β-(aminoethyl)-γ-aminopropylmethyl dimethoxy silane, γ-aminopropyl triethoxy silane, and N-phenyl-γ-aminopropyl trimethoxy silane; γ-mercaptopropyl trimethoxy silane, and γ-chloropropyl trimethoxy silane. Examples of the titanate-based coupling agent include isopropyl triisostearoyl titanate, isopropyl tridecyl benzenesulfonyl titanate, isopropyl tris(dioctyl pyrophosphate) titanate, tetraisopropyl bis(dioctyl phosphate) titanate, tetra(2,2-diallyloxymethyl-1-butyl) bis(di-tridecyl)phosphate titanate, bis(dioctyl pyrophosphate)oxyacetate titanate, bis(dioctyl pyrophosphate)ethylene titanate, isopropyl trioctanoyl titanate, and isopropyl tricumyl phenyl titanate.

The coupling agent may be preferably a silane-based coupling agent, more preferably an aminosilane-based coupling agents such as γ-aminopropyl-triethoxy silane, N-β-(aminoethyl)-γ-aminopropyl-triethoxy silane, N-(aminocarbonyl)-γ-aminopropyl triethoxy silane, N-[β-(phenylamino)-ethyl]-γ-aminopropyl triethoxy silane, N-phenyl-γ-aminopropyl triethoxy silane, and N-phenyl-γ-aminopropyl trimethoxy silane. Among them, N-phenyl-γ-aminopropyl trimethoxy silane is particularly preferable.

Examples of the solvent for the coupling agent solution may include those listed as the organic solvent for the polyimide precursor solution (the solvent contained in the self-supporting film). The preferable organic solvent is a solvent compatible with the polyimide precursor solution, and is the same as the organic solvent for the polyimide precursor solution. The organic solvent may be a mixture of two or more compounds.

The content of the coupling agent in the coupling agent solution (the organic solvent solution) may be preferably 0.5 wt % or more, more preferably 1 wt % to 100 wt %, particularly preferably 3 wt % to 60 wt %, further preferably 5 wt % to 55 wt %. The content of water in the coupling agent solution may be preferably 20 wt % or less, more preferably 10 wt % or less, particularly preferably 5 wt % or less. A solution of a coupling agent in an organic solvent may preferably have a rotational viscosity (a solution viscosity measured with a rotation viscometer at a measurement temperature of 25° C.) of 10 to 50,000 centipoise.

A particularly preferable solution of a coupling agent in an organic solvent may have a low viscosity (specifically, rotational viscosity: 10 to 5,000 centipoise) and comprise a coupling agent, which is homogeneously dissolved in an amide solvent, in an amount of 0.5 wt % or more, more preferably 1 wt % to 60 wt %, further preferably 3 wt % to 55 wt %.

The amount of the coupling agent solution to be applied to a self-supporting film may be appropriately determined. For example, it is preferably 1 to 50 g/m², more preferably 2 to 30 g/m², particularly preferably 3 to 20 g/m² for one side (Side B) of the self-supporting film which was in contact with the support when producing the film.

The coupling agent solution may be applied by any known method; for example, by gravure coating, spin coating, silk screen coating, dip coating, spray coating, bar coating, knife coating, roll coating, blade coating, and die coating.

According to the present invention, the self-supporting film on which a coupling agent solution is applied is then heated to effect imidization, thereby producing a polyimide film.

As described above, according to the present invention, the curling may be controlled by adjusting the inlet temperature of the heating furnace for heating the self-supporting film to effect imidization (curing oven), i.e. the initiation temperature of the heat treatment.

The preferable heat treatment may be a process in which polymer imidization and solvent evaporation/removal are gradually conducted at about 100 to 400° C. for about 0.05 to 5 hours, particularly 0.1 to 3 hours as the first step. This heat treatment is particularly preferably conducted stepwise, that is, the first heat treatment at a relatively lower temperature of about 100 to 170° C. for about 0.5 to 30 min, the second heat treatment at 170 to 220° C. for about 0.5 to 30 min, and then the third heat treatment at a high temperature of 220 to 400° C. for about 0.5 to 30 min. If necessary, the fourth high-temperature heat treatment at 400 to 550° C. may be conducted.

It is preferable to fix at least both edges of a long solidified film in the direction perpendicular to the length direction, i.e. in the width direction, with a pintenter, a clip or a frame, for example, while heating in a curing oven. As described above, according to the present invention, the curling may be controlled by adjusting the width of the film at that time; specifically by stretching the film in the width direction in the curing oven.

The thickness of the polyimide film obtained according to the present invention may be about 5 μm to 125 μm, preferably 7.5 μm to 125 μm, more preferably 10 μm to 100 μm, particularly preferably 17 μm to 38 μm.

According to the present invention, a polyimide film in which the curling is controlled and the curling surface is Side A may be obtained. In addition, a polyimide film obtained according to the present invention may have one side onto which a coupling agent solution is applied (Side B) with improved adhesive properties, sputtering properties, and metal vapor deposition properties. Therefore, a metal-laminated polyimide film such as a copper-laminated polyimide film having sufficiently high peel strength may be obtained by forming a metal layer on Side B of the polyimide film by a metallizing method, and then forming a metal plated layer such as a copper plated layer on the metal layer by a metal plating method.

A metal sputtered underlayer may be formed by a metallizing method on a side of the polyimide film of the present invention onto which a coupling agent solution is applied. The metallizing method is a method for forming a metal layer which is different from a metal plating method or a metal foil lamination method, and any known method such as vapor deposition, sputtering, ion plating and electron-beam evaporation may be employed.

Examples of a metal used in the metallizing method include, but not limited to, metals such as copper, nickel, chromium, manganese, aluminum, iron, molybdenum, cobalt, tungsten, vanadium, titanium and tantalum, and alloys thereof, oxides thereof, and carbides thereof.

A thickness of a metal layer formed by a metallizing method may be appropriately determined depending on an intended application. It may be preferably 1 nm to 500 nm, more preferably 5 nm to 200 nm for a practical use.

The number of metal layers formed by a metallizing method may be appropriately determined depending on an intended application, and may be one, two, three or more layers.

A metal plated layer such as a copper plated layer and a tin plated layer may be formed by a known wet plating process such as electrolytic plating and electroless plating on the surface of the metal layer, which is formed by a metallizing method.

The metal-laminated polyimide film may preferably have a metal plated layer such as a copper plated layer with a thickness of 1 μm to 9 μm for a practical use.

A metal layer formed by a metallizing method may consist of two layers, that is, a Ni/Cr alloy layer with a thickness of 1 nm to 30 nm and a copper sputtered layer with a thickness of 100 nm to 1000 nm, for example. A copper plated layer with a thickness of 1 μm to 9 μm may be formed on the metal layer, which is formed by a metallizing method.

The wiring board of the present invention may be obtained by etching the metal layer of the metal-laminated polyimide film thus obtained to form a metal wiring. A metal layer may be etched by a known method.

### EXAMPLES

The present invention will be described in more detail below with reference to the Examples. However, the present invention is not limited to these Examples.

### Reference Example

Into a polymerization tank were placed the given amounts of N,N-dimethylacetamide, 3,3′,4,4′-biphenyltetracarboxylic dianhydride, and p-phenylenediamine in this order. And then, the resulting mixture was reacted at 30° C. for 10 hours, to give a polyimide precursor solution having a polymer logarithmic viscosity (measurement temperature: 30° C.; concentration: 0.5 g/100 mL; solvent: N,N-dimethylacetamide) of 1.60 and a polymer concentration of 18 wt %. To the polyimide precursor solution were added 0.1 parts by weight of triethanolamine salt of monostearyl phosphate and 0.5 parts by weight of colloidal silica (average particle size: 80 nm) relative to 100 parts by weight of the polyimide precursor, and the resulting mixture was homogeneously mixed, to give a polyimide precursor solution composition. The polyimide precursor solution composition thus obtained had a rotational viscosity at 25° C. of about 3,000 poise.

### Example 1

The polyimide precursor solution composition prepared in Reference Example was continuously cast from a slit of a T-die mold on a smooth metal support in a drying oven, to form a thin film on the support. The thin film was heated at 145° C. for a predetermined time, and then peeled off from the support to give a self-supporting film. The content of the solvent in the self-supporting film was 38.7 wt %.

Then, 5 wt % solution of a silane coupling agent (N-phenyl-γ-aminopropyl triethoxy silane) in N,N-dimethylacetamide was applied on a side (side B) of the self-supporting film which had been in contact with the support at the application amount of 10 g/m², and then the self-supporting film was dried under hot air at 100° C. to 105° C. Subsequently, the self-supporting film was fed into a continuous heating oven (curing oven) while fixing both edges of the film in the width direction, and the film was heated from 150° C. to the highest heating temperature of 480° C. in the oven to effect imidization, thereby continuously producing a long polyimide film having a curling amount of −21.8 mm and an average thickness of 35 μm. The conditions for producing the polyimide film (casting temperature) and the content of the solvent in the self-supporting film obtained are shown in Table 1.

A metal sputtered underlayer consisting of a Ni/Cr (weight ratio: 8/2) layer having a thickness of 5 nm and a Cu layer having a thickness of 400 nm was formed on Side B of the polyimide film obtained by a conventional method. Subsequently, a copper plated layer having a thickness of 8 μm was formed by copper plating on the metal sputtered underlayer, to give a copper-laminated polyimide film. And then, a rectangular sample (70 mm×50 mm; 70 mm was in the direction of the TD of the long polyimide film) was cut out from the copper-laminated polyimide film. The copper layer of the sample was etched by a conventional method to form a straight wiring having a Cu remaining ratio of 80% (100 μm pitch; line/space=80 μm/20 μm in the major portion) or 50% (100 μm pitch; line/space=50 μm/50 μm in the major portion) along the direction of the short side, thereby producing a copper-wiring polyimide film (wiring board). The drooping amount of each copper-wiring polyimide film was determined. The results are shown in Table 2. The curling amount of the polyimide film was also determined, and the result is shown in Table 2.

### Example 2

### Comparative Examples 1-2

A polyimide film was produced in the same way as in Example 1, except that the heating temperature and the heating time for heating the thin film to prepare the self-supporting film were changed. The heating temperature of the thin film (casting temperature for the preparation of the self-supporting film) and the content of the solvent in the self-supporting film obtained are shown in Table 1.

A copper-wiring polyimide film was produced from the polyimide film thus obtained in the same way as in Example 1, and the drooping amount of the copper-wiring polyimide film was determined. The results are shown in Table 2. The curling amount of the polyimide film was also determined, and the result is shown in Table 2.

TABLE 1

| | Casting Temp. | Content of Solvent in |
|---|---|---|
| | (° C.) | Self-supporting Film (wt %) |
| Example 1 | 145 | 38.7 |
| Example 2 | 150 | 38.3 |
| Comparative Example 1 | 150 | 36.8 |
| Comparative Example 2 | 160 | 36.1 |

TABLE 2

| | | Drooping Amount of Wiring Board | |
|---|---|---|---|
| | Curling | 70 mm × 50 mm | 70 mm × 50 mm |
| | Amount | Cu Remaining | Cu Remaining |
| | (mm) | Ratio: 80% | Ratio: 50% |
| Example 1 | −21.8 | −3.4 | −1.0 |
| Example 2 | −20.4 | −3.4 | −1.0 |
| Comparative Example 1 | −12 | −7.1 | −3.2 |
| Comparative Example 2 | −8 | −7.9 | −5.3 |

### INDUSTRIAL APPLICABILITY

As described above, according to the present invention, a polyimide film in which the curling is controlled may be used for COF to enhance handling characteristics and productivity in IC chip mounting.

1. A polyimide film produced by
providing a solution of a polyimide precursor prepared from an aromatic tetracarboxylic acid component comprising 3,3′,4,4′-biphenyltetracarboxylic dianhydride as a main component and an aromatic diamine component comprising p-phenylenediamine as a main component;
flow-casting the polyimide precursor solution on a support, followed by heating, thereby preparing a self-supporting film of a polyimide precursor solution;
applying a solution containing a coupling agent onto one side (Side B) of the self-supporting film which has been in contact with the support when producing the film; and
heating the self-supporting film onto which the coupling agent solution is applied to effect imidization;
wherein the polyimide film is to be used for the production of a wiring board having a metal wiring, which is formed by forming a metal layer on one side (Side B) of the polyimide film, and etching the metal layer; the polyimide film is curled toward the side (Side A) opposite Side B; and the curling of the polyimide film is controlled so as to reduce the drooping of the wiring board having a metal wiring formed thereon.

2. The polyimide film as claimed in claim 1, wherein the curling of the polyimide film is controlled so that the absolute value of the drooping amount of the wiring board having a metal wiring formed thereon (70 mm×50 mm, the remaining ratio of the metal layer: 50%) is 3.0 mm or less.

3. The polyimide film as claimed in claim 1, wherein the metal wiring is a copper wiring.

4. The polyimide film as claimed in claim 1, wherein the coupling agent is a silane coupling agent.

5. The polyimide film as claimed in claim 1, wherein the curling of the polyimide film is controlled by adjusting at least one of the content of the solvent in the self-supporting film, the inlet temperature of the heating furnace for heating the self-supporting film to effect imidization, and the width of the film when both widthwise edges of the film are fixed in the heating furnace.

6. A wiring board produced by
providing a solution of a polyimide precursor prepared from an aromatic tetracarboxylic acid component comprising 3,3′,4,4′-biphenyltetracarboxylic dianhydride as a main component and an aromatic diamine component comprising p-phenylenediamine as a main component;
flow-casting the polyimide precursor solution on a support, followed by heating, thereby preparing a self-supporting film of a polyimide precursor solution;
applying a solution containing a coupling agent onto one side (Side B) of the self-supporting film which has been in contact with the support when producing the film;
heating the self-supporting film onto which the coupling agent solution is applied to effect imidization, thereby preparing a polyimide film;
forming a metal layer on one side (Side B) of the polyimide film; and
etching the metal layer to form a metal wiring;
wherein the polyimide film is curled toward the side (Side A) opposite Side B;
and the curling of the polyimide film is controlled so as to reduce the drooping of the wiring board having a metal wiring formed on Side B of the polyimide film.

7. The wiring board as claimed in claim 6, wherein the absolute value of the drooping amount of the wiring board having a metal wiring formed thereon (70 mm×50 mm, the remaining ratio of the metal layer: 50%) is 3.0 mm or less.

8. The wiring board as claimed in claim 6, wherein the metal wiring is a copper wiring.

9. The wiring board as claimed in claim 6, wherein the coupling agent is a silane coupling agent.

10. The wiring board as claimed in claim 6, wherein the curling of the polyimide film is controlled by adjusting at least one of the content of the solvent in the self-supporting film, the inlet temperature of the heating furnace for heating the self-supporting film to effect imidization, and the width of the film when both widthwise edges of the film are fixed in the heating furnace.

11. The wiring board as claimed in claim 6, wherein the metal layer consists of a metal sputtered underlayer consisting of a Ni/Cr layer having a thickness of 1 nm to 30 nm and a copper sputtered layer having a thickness of 100 nm to 1000 nm, and a copper plated layer having a thickness of 1 μm to 9 μm.
